(19) United States
(12) Patent Application Publication
(10) Pub. No.: US 2025/0092509 A1
(43) Pub. Date: Mar. 20, 2025

(54) SELECTIVE DEPOSITION OF ORGANIC POLYMER MATERIAL AND DEPOSITION ASSEMBLIES

(71) Applicant: ASM IP Holding B.V., Almere (NL)

(72) Inventors: Bhagyesh Purohit, Helsinki (FI); Saima Alli, Helsinki (FI); Eva E. Tois, Espoo (FI); Marko Tuominen, Helsinki (FI); Charles Dezelah, Helsinki (FI); Vincent Vandalon, Heverlee (BE); Adam Vianna, Phoenix, AZ (US); Krzysztof Kamil Kachel, Chandler, AZ (US); Eric James Shero, Phoenix, AZ (US); Yi Cheng Zhang, Scottsdale, AZ (US); Anirudhan Chandrasekaran, Scottsdale, AZ (US)

(21) Appl. No.: 18/889,069

(22) Filed: Sep. 18, 2024

Related U.S. Application Data
(60) Provisional application No. 63/583,752, filed on Sep. 19, 2023.

(51) Int. Cl. C23C 16/04; C23C 16/455; C23C 16/56; H01L 21/02

(52) U.S. Cl. CPC C23C 16/04; C23C 16/45553; C23C 16/56; H01L 21/02118; H01L 21/0228

(57) ABSTRACT

The disclosure relates to methods and processing assemblies for selectively depositing organic polymer material on a first surface of a substrate relative to a second surface of the substrate by a cyclic deposition process is disclosed. The method comprises providing a substrate in a reaction chamber, providing a first vapor-phase organic reactant into the reaction chamber and providing a second vapor-phase organic reactant into the reaction chamber. In the method, the first and second vapor-phase organic reactants form the organic polymer material selectively on the first surface; and the first vapor-phase reactant comprises a cyclic compound comprising at least two primary amine groups.

### CROSS-REFERENCE TO RELATED APPLICATION(S)

This application claims the benefit of U.S. Provisional Application 63/583,752 filed on Sep. 19, 2023, the entire contents of which are incorporated herein by reference.

### FIELD

The present disclosure generally relates to methods and assemblies selectively depositing materials on substrate surfaces having different compositions. Such methods may be used for, for example, processing semiconductor substrates. More particularly, the disclosure relates to methods and assemblies for selectively depositing organic polymer material on a first surface of a substrate relative to a second surface of the substrate, and to methods of depositing dielectric materials.

### BACKGROUND

Semiconductor device fabrication processes generally use advanced deposition methods. Patterning is conventionally used in depositing different materials on semiconductor substrates. Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing.

Organic polymer layers can be used, for example, as a starting point in semiconductor applications for amorphous carbon films or layers. As an example, polyimide-containing layers are valuable for their thermal stability and resistance to mechanical stress and chemicals, and they have been described as passivation layers to allow selective deposition of different materials. Vapor-phase deposition processes, such as chemical vapor deposition (CVD), vapor deposition polymerization (VDP), molecular layer deposition (MLD) may be used to deposit organic polymer layers. In such processes, the precursors used to deposit the material have an important role in the properties of the deposited layers. This, again, affects the material's usability when different materials are selectively deposited on different surface combinations.

In addition to the properties of the organic polymer material, precursors differ in their physical properties, affecting the ease of handling of the precursors, as well as the possible parameter range during deposition. Thus, a need exists in the art to broaden the selection of precursors for the deposition of organic polymer layers.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods of depositing organic polymer material, passivation material and dielectric material; and particularly selectively depositing organic polymer material, passivation material and dielectric material. Embodiments of the current disclosure further relate to methods of depositing organic polymer material, fabricating semiconductor devices, and to semiconductor processing assemblies.

In one aspect, a method of selectively depositing organic polymer material on a first surface of a substrate relative to a second surface of the substrate by a cyclic deposition process is disclosed. The method comprises providing a substrate in a reaction chamber, providing a first vapor-phase organic reactant into the reaction chamber and providing a second vapor-phase organic reactant into the reaction chamber. In the method, the first and second vapor-phase organic reactants form the organic polymer material selectively on the first surface; and the first vapor-phase reactant comprises a cyclic compound comprising at least two primary amine groups.

In some embodiments, the second vapor-phase reactant comprises a dianhydride.

In some embodiments, the cyclic compound comprises a carbocycle. In some embodiments, the cyclic compound comprises an aromatic ring. In some embodiments, the cyclic compound comprises an alicyclic ring. In some embodiments, the cyclic compound comprises a six-membered carbocycle comprising two primary amine groups, bonded directly or indirectly to positions 1 and 4 of the carbon ring, respectively. In some embodiments, the cyclic compound comprises a six-membered carbocycle comprising three primary amine groups, bonded directly or indirectly to positions 1, 3 and 5 of the carbon ring, respectively. In some embodiments, the cyclic compound comprises at least one of cyclopentanedialkanamine, cyclohexanedialkanamine, cyclopentadienedialkanamine, benzenedialkanamine, cyclopentanetrialkanamine, cyclohexanetrialkanamine, cyclopentadienetrialkanamine and benzenetrialkanamine. In some embodiments, the cyclic compound is selected from a group consisting of 1,3-cyclopentanediamine, 3,5-cyclopentadiene-1,3-diamine, 2,4-cyclopentadiene-1,3-diamine, 1,3-cyclopentanedimethanamine, 3,5-cyclopentadiene-1,3-dimethanamine, 2,4-cyclopentadiene-1,3-dimethanamine, 1,4-diaminocyclohexane, 1,3 cyclohexanediamine, 1,2-cyclohexanediamine, 1,4-cyclohexanedimethanamine, 1,3-cyclohexanedimethanamine, 1,2-cyclohexanedimethanamine, 1,4-cyclohexanediethanamine, 1,3-cyclohexanediethanamine, 1,2-cyclohexanediethanamine, 1,2,3-cyclopentanetriamine, 1,2,4-cyclopentanetriamine, 1,3-cyclopentadiene-1,2,4-triamine, 1,2,3-cyclohexanetriamine, 1,2,4-cyclohexanetriamine, 1,3,5-cyclohexanetriamine, 1,3,5-cyclohexanetrimethanamine, p-phenylenediamine, m-phenylenediamine, o-phenylenediamine, 1,4-benzenedimethanamine, 1,3-benzenedimethanamine, 1,2-benzenedimethanamine, 1,2,3-benzenetriamine, 1,2,4-benzenetriamine, 1,3,5-benzenetriamine, 1,2,3-benzenetrimethanamine, 1,2,4-benzenetrimethanamine and 1,3,5-benzenetrimethanamine.

In some embodiments, the organic polymer material comprises polyimide. In some embodiments, the organic polymer material comprises polyamic acid.

In some embodiments, the substrate is held at a temperature of between about 100° C. and about 200° C. during deposition of the organic polymer material. In some embodiments, the organic polymer material is deposited on the first surface relative to the second surface with a selectivity of about 50% or higher. In some embodiments, the ratio of vertical growth to lateral growth of the organic polymer material over the first surface is at least 2.5.

In some embodiments, the first surface comprises a dielectric surface. In some embodiments, the first surface comprises silicon. In some embodiments, the first surface comprises SiO₂. In some embodiments, the first surface comprises a metal oxide, elemental metal, or metallic surface. In some embodiments, the first surface comprises a metal selected from a group consisting of zirconium, hafnium, vanadium, niobium, tantalum, molybdenum, tungsten, iron, ruthenium, cobalt, nickel, copper, zinc, aluminum, gallium, indium and tin.

In another aspect, a method of selectively depositing organic passivation material on a first surface of a substrate relative to a second surface of the substrate is disclosed. The method comprises providing a substrate in a reaction chamber, providing a first vapor-phase organic reactant into the reaction chamber and providing a second vapor-phase organic reactant into the reaction chamber. In the method, the first and second vapor-phase organic reactants form the organic passivation material selectively on the first surface and the first vapor-phase precursor comprises a cyclic compound comprising at least two primary amine groups.

In another aspect, a method of selectively depositing a dielectric material on a second surface of a substrate is disclosed. The method comprises selectively depositing organic passivation material on the first surface of the substrate according to the current disclosure before depositing the dielectric material.

In some embodiments, the dielectric material is deposited by a cyclic deposition process.

In a further aspect, a semiconductor processing assembly for selectively depositing an organic polymer material on a first surface of a substrate is disclosed. The semiconductor processing assembly comprises one or more reaction chambers constructed and arranged to hold the substrate and a precursor injector system constructed and arranged to provide a first organic reactant and a second organic reactant into the reaction chamber in a vapor phase. The semiconductor processing assembly further comprises a first organic reactant source vessel constructed and arranged to contain the first organic reactant and a second organic reactant source vessel constructed and arranged to contain the second organic reactant. The semiconductor processing assembly is constructed and arranged to provide the first organic reactant and the second organic reactant into the reaction chamber for selectively forming organic polymer material on the first surface of the substrate. In some embodiments, the semiconductor processing assembly further comprises one or more precursor source vessels, and wherein the precursor injector system is constructed and arranged to provide one or more precursors from the one or more precursor source vessels into the reaction chamber in a vapor phase for selectively depositing dielectric material on the second surface of the substrate.

In a yet further aspect, a method of depositing organic polymer material on a substrate by a vapor deposition process is disclosed. The method comprises providing a substrate in a reaction chamber,
providing a first vapor-phase organic reactant comprising a cyclic compound comprising at least two primary amine groups into the reaction chamber and polymerizing the first vapor-phase organic reactant on a surface of a substrate.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of an exemplary embodiment of a method of selectively depositing organic polymer material according to the current disclosure.

FIGS. 2a)-2e) show a schematic presentation of exemplary embodiments of methods according to the current disclosure.

FIG. 3 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular layer, structure, device or a processing assembly, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

In this disclosure, “gas” can include material that is a gas at normal temperature and pressure (NTP), a vaporized solid and/or a vaporized liquid, and can be constituted by a single gas or a mixture of gases, depending on the context. Reactants and precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction chamber, and can include a seal gas.

The term “dielectric” is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes of inhibitor material taught herein can deposit on dielectric surfaces with minimal deposition on such adjacent non-conductive metal or metallic surfaces.

As used herein, a “precursor” and a “reactant” refer to a compound that participates in a chemical reaction to form another compound or element, wherein a portion of the precursor (an element or group within the precursor) is incorporated into the compound or element that results from the chemical reaction. The compound or element that results from the chemical reaction may be material, a layer and/or a film that is formed on a surface of a substrate. As used herein, a “reactant” refers to a compound that participates in a chemical reaction to form another compound or element. In some instances, a reactant is a precursor. In other instances, the compound or element that results from the chemical reaction does not contain a portion of the reactant (an element or group within the reactant) and therefore the reactant is not a precursor.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a liquid or a gas in standard conditions.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### Substrate

In one aspect, a method of selectively depositing organic polymer material on a first surface of a substrate relative to a second surface of the substrate by a cyclic deposition process is disclosed. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

In the methods according to the current disclosure, the first and second vapor-phase organic reactants form the organic polymer material selectively on the first surface. A substrate according to the current disclosure thus comprises a first surface and a second surface. The first surface and the second surface have different material properties, allowing for the selective deposition of a polymer material on the first surface. In some embodiments, the first surface and the second surface are adjacent to each other. In some embodiments, the first surface and the second surface are on the same face of a silicon wafer.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of selectively depositing organic polymer material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of the methods according to the current disclosure, such as methods of depositing an organic polymer material, or methods of selectively depositing organic passivation material or a dielectric material, can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrate and/or the reactants and/or precursors.

### Cyclic Vapor Deposition

The selective deposition methods comprise providing a first vapor-phase organic reactant into the reaction chamber and providing a second vapor-phase organic reactant into the reaction chamber. The reactants may be provided into the reaction chamber alternately. The reactants may be provided into the reaction chamber sequentially. Thus, in some methods according to the current disclosure, particularly those of depositing organic polymer material, organic passivation layer and dielectric material, cyclic vapor deposition methods may be used. Cyclic deposition in the current disclosure refers to vapor deposition processes in which deposition cycles, typically a plurality of consecutive deposition cycles, are conducted in a process chamber. For clarity, the deposition of inhibitor material according to the current disclosure may be a non-cyclic process, in which the inhibitor reactant

Generally, in cyclic deposition processes according to the current disclosure, such as atomic layer deposition (ALD) and molecular layer deposition (MLD), during each cycle, a precursor or a reactant is introduced to a reaction chamber and is chemisorbed to a substrate surface (e.g., a substrate surface that may include a previously deposited material from a previous deposition cycle or other material). In some embodiments, the precursor or a reactant on the substrate surface does not readily react with additional precursor or a reactant (i.e., the deposition of the precursor may be a partially or fully self-limiting reaction). Thereafter, another precursor or a reactant may be introduced into the reaction chamber for use in converting the chemisorbed precursor or a reactant to the desired material on the deposition surface. The second precursor or a reactant can be capable of further reaction with the precursor. Purging steps may be utilized during one or more cycles, e.g., during each step of each cycle, to remove any excess precursor or reactant from the process chamber and/or remove any excess precursors or reactant and/or reaction byproducts from the reaction chamber. Thus, in some embodiments, the cyclic deposition process comprises purging the reaction chamber after providing a precursor or a reactant into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, such as a dielectric material, whereas in MLD, the precursors or reactants may be fully organic molecules, such as when organic polymer material is deposited.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction chamber or substrate, or in partially or completely separated pulses. However, CVD may be performed with a single precursor, or two or more precursors that do not react with each other. A single precursor or a reactant may decompose into reactive components that are deposited on the substrate surface. The decomposition may be brought about by plasma or thermal means, for example. The substrate and/or reaction chamber can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises or one or more acyclic (i.e. continuous) phases. An example of a continuous phase could be a pre-treatment with a single reactant or forming of inhibitor material on a substrate. In some embodiments, the deposition process comprises the continuous flow of at least one precursor or a reactant. In some embodiments, one or more of the precursors or reactants are provided in the reaction chamber continuously.

In some embodiments, the organic polymer material according to the current disclosure is deposited at a pressure of at least 0.01 Torr to at most 300 Torr, or at a pressure of at least 0.1 Torr to at most 150 Torr, or at a pressure of at least 0.5 Torr to at most 25 Torr, or at a pressure of at least 1 Torr to at most 10 Torr, or at a pressure of at least 2 Torr to at most 5 Torr. For example, the inhibitor material may be deposited at a pressure of about 1 Torr, about 2 Torr, about 3 Torr, about 6 Torr, about 8 Torr, about 9 Torr, about 12 Torr or about 18 Torr. In some embodiments, further processing steps are performed at the same pressure. In some embodiments, further processing steps are performed at a different pressure, which may be lower or higher than the pressure at which organic polymer material is deposited.

In some embodiments, the cyclic vapor deposition processes according to the current disclosure comprises a thermal deposition process. In thermal deposition, the chemical reactions are promoted by increased temperature relevant to ambient temperature. Generally, temperature increase provides the energy needed for the formation of the target material in the absence of other external energy sources, such as plasma, radicals, or other forms of radiation. However, in some embodiments, the methods according to the current disclosure, especially methods of depositing dielectric material, comprise a plasma-enhanced deposition method, for example PEALD or PECVD. For example, in some embodiments, an inhibitor material deposition may be performed by PEALD or PECVD.

### Selectivity

The current disclosure relates to selective deposition processes. When deposition is performed selectively on a first surface of the substrate relative to a second surface of the substrate, selectivity can be given as a percentage calculated by [(deposition on first surface)-(deposition on second surface)]/(deposition on the first surface). When a target material is deposited on the second surface, the calculation is reversed accordingly.

In some embodiments, selectivity is at least about 30%. In some embodiments, selectivity is at least about 50%. In some embodiments, selectivity is at least about 75% or greater than about 85%. In some embodiments, selectivity is at least about 90% or at least about 93%. In some embodiments, selectivity is at least about 95% or at least about 98%. In some embodiments, selectivity is at least about 99% or even at least about 99.5%. In embodiments, the selectivity can change over the duration or thickness of a deposition.

Deposition can be measured in any of a variety of ways. In some embodiments, deposition may be given as the measured thickness of the deposited material. In some embodiments, deposition may be given as the measured amount of deposited material. Sometimes selectivity, for example after treating one of at least two surfaces of a substrate with an inhibitor or passivation material, may be measured as nucleation delay expressed as number of deposition cycles before target material growth is observed on the different surfaces. In such cases, the term “selectivity window” can be used to describe the difference between the number of cycles on the different surfaces before growth of a target material is observed.

In some embodiments, the organic polymer material is deposited substantially only on the first surface and not on the second surface. Thus, deposition of the organic polymer material only occurs on one surface, such as the first surface, and does substantially not occur on the other surface(s). In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition of the organic polymer material is inherent, and no preceding or additional processing steps over those conveniently performed on a substrate are necessary. Selectivity may be inherent to a certain thickness of deposited material, and be lost in case deposition is continued beyond a process-specific threshold. If thicker material layers are desired, the contrast between the first surface and the second surface may be enhanced though, for example, intermittent etch-back phase. Plasma, such as hydrogen plasma, may be used.

Before the organic polymer material is deposited on the first surface, the second surface, such as a dielectric surface or a metal or a metallic surface, may be selectively silylated relative to the first surface by a silylating agent. In some embodiments, the second surface is a dielectric surface or a surface comprising silicon and it is silylated by exposure to a silylation agent, such as an alkylsilane, for example allyltrimethylsilane (TMS-A), halosilane, for example chlorotrimethylsilane (TMS-Cl) or octadecyltrichlorosilane (ODTCS), an imidazole, for example N-(trimenthylsilyl) imidazole (TMS-Im), a silazane, for example hexamethyldisilazane (HMDS), or a silylamine, for example N-(trimethylsilyl)dimethylamine (TMSDMA). In some embodiments, the second surface is a metal or a metallic surface, and it is silylated by an alkylsilane having at least one alkoxy group bonded to a silicon atom, such as by an inhibitor reactant represented by a formula SiₐRₓ(OH)_{y}(OR′)_{z}, wherein a is 1, 2 or 3, x is 1, 2 or 3, y is 0, 1 or 2, and z is 1, 2 or 3, with the proviso that x+y+z=a+2, and each R and R′ is independently selected from linear and branched C₁ to C₈ alkyls. In some embodiments, a second metal or metallic surface is treated with an inhibitor reactant, wherein R′ is branched. In some embodiments, R is linear. In some embodiments, R and R′ are saturated. In some embodiments, R′ is selected from, isopropyl, sec-butyl, tert-butyl, 1,1-dimethylpropyl, 2,2-dimethylpropyl, 1-methylbutyl, 3-methylbutyl, 3-pentyl, 1,2-dimethylpropyl and 2-methylbutyl. In some embodiments, the inhibitor reactant is selected from Si(OH)₂R(OR′), Si(OH)R₂(OR′), Si(OH)R(OR′)₂, R(OR′)(OH)Si—Si(OH)R(OR′), Si₂(OH)₂R₂(OR′)₂, Si₂(OH)R₂(OR′)₂, SiR(OR′)₃, SiR₂(OR′)₂, SiR₃(OR′), R₂(OR′)Si—SiR₂(OR′), R(OR′)₂Si—SiR(OR′)₂. In some embodiments, each R is methyl or ethyl.

In some embodiments, the inhibitor reactant is selected from a group consisting of Si(OH)CH₃(OCH(CH₃)₂)₂, Si(OH)₂CH₃(OCH(CH₃)₂), Si(OH)(CH₃)₂(OCH(CH₃)₂), Si(OH)₂CH₃(OC(CH₃)₃), Si(OH)(CH₃)₂ (OC(CH₃)₃), Si(OH)(CH₂CH₃)₂(OC(CH₃)₃), Si(OH)₂CH₃[(CH₃)₂ (CH₂CH₃)], Si(OH)CH₃(OC[(CH₃)₂(CH₂CH₃)])₂, Si(OH)CH₃(OC(CH₃)₃)₂, Si(OH)CH₂CH₃(OC(CH₃)₃)₂, Si(OH)(CH₃)₂[(CH₃)₂ (CH₂CH₃)], SiCH₃(OCH(CH₃)₂)₃, Si(CH₃)₂ (OCH(CH₃)₂)₂, Si(CH₃)₃(OCH(CH₃)₂), SiCH₃(OC(CH₃)₃)₃, Si(CH₃)₂ (OC(CH₃)₃)₂, Si(CH₃)₃(OC(CH₃)₃), Si(CH₂CH₃)(OC(CH₃)₃)₃, Si(CH₂CH₃)₂ (OC(CH₃)₃)₂, Si(CH₂CH₃)₃(OC(CH₃)₃), SiCH₃(OC [(CH₃)₂ (CH₂CH₃)])₃, Si(CH₃)₂[(CH₃)₂ (CH₂CH₃)]₂ and Si(CH₃)₃[(CH₃)₂ (CH₂CH₃)].
providing a first vapor-phase organic reactant into the reaction chamber and providing a second vapor-phase organic reactant into the reaction chamber, and the first vapor-phase reactant comprises a cyclic compound comprising at least two primary amine groups.

### DRAWINGS

The disclosure is further explained by the following exemplary embodiments depicted in the drawings. The illustrations presented herein are not meant to be actual views of any particular material or a deposition assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. Specifically, relative etch rates of different materials indicated in the drawings may deviate from the experimental results, the specifics of which may vary according to process conditions. The layers, structures, devices and processing assemblies depicted in the drawings may contain additional elements and details, which may be omitted for clarity.

For the sake of brevity, conventional manufacturing, connection, preparation, and other functional aspects of the methods, layers, structures, devices and processing assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

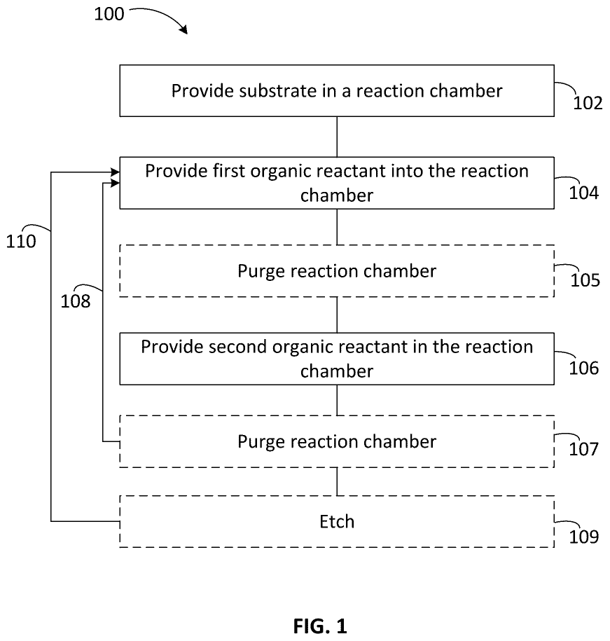

FIG. 1 is a block diagram of an exemplary embodiment of a method 100 according to the current disclosure. First, a substrate is provided in a reaction chamber at stage 102. The substrate comprises a first surface and a second surface as described in the current disclosure.

For embodiments in which one surface of the substrate comprises a metal, the surface is referred to as a metal surface. In some embodiments, a metal surface consists essentially of, or consists of one or more metals. A metal surface may be a metal surface or a metallic surface. In some embodiments the metal or metallic surface may comprise metal, metal oxides, and/or mixtures thereof. In some embodiments the metal or metallic surface may comprise surface oxidation. In some embodiments the metal or metallic material of the metal or metallic surface is electrically conductive with or without surface oxidation. In some embodiments, metal or a metallic surface comprises one or more transition metals.

In some embodiments, the first surface is a metal or a metallic surface and the second surface is a dielectric surface. In some embodiments, the first surface is a metal or a metallic surface and the second surface is a silicon-comprising surface. In some embodiments, the first surface is a dielectric surface and the second surface is a metal or a metallic surface. In some embodiments, the first surface is a silicon-comprising surface and the second surface is a metal or a metallic surface. As described in the current disclosure, the deposition of the organic polymer material can be directed selectively on either metal or metallic surfaces or on dielectric materials and/or silicon-comprising materials.

In some embodiments, organic polymer material is selectively deposited on a first dielectric surface of a substrate relative to a second conductive (e.g., metal or metallic) surface of the substrate. In some embodiments, organic polymer material is selectively deposited on a first conductive (e.g., metal or metallic) surface of a substrate relative to a second dielectric surface of the substrate.

In some embodiments, the first surface is a dielectric surface, and the second surface is a metal surface. In some embodiments, the first surface is a silicon-comprising dielectric surface and the second surface is a metal surface. In some embodiments, the first surface is a high-k surface and the second surface is a metal surface. In some embodiments, the first surface is a metal oxide surface and the second surface is a metal surface. In some embodiments, the first surface comprises a material selected from a group consisting of HfO₂, ZrO₂, Al₂O₃ and Y₂O₃.

In some embodiments, the second surface is a dielectric surface, and the first surface is a metal surface. In some embodiments, the second surface is a silicon-comprising dielectric surface and the first surface is a metal surface. In some embodiments, the second surface is a high-k surface and the first surface is a metal surface. In some embodiments, the second surface is a metal oxide surface and the first surface is a metal surface. In some embodiments, the second surface comprises a material selected from a group consisting of HfO₂, ZrO₂, Al₂O₃ and Y₂O₃.

In some embodiments, the first surface comprises a dielectric surface. In some embodiments, the first surface comprises a material selected from a group consisting of a metal, amorphous carbon, metal oxide and metal nitride. In some embodiments, the second surface comprises a dielectric surface. In some embodiments, the second surface comprises a material selected from a group consisting of a metal, amorphous carbon, metal oxide and metal nitride.

In some embodiments, the second surface comprises a dielectric surface. In some embodiments, the second surface comprises a material selected from a group consisting of a metal, amorphous carbon, metal oxide and metal nitride. In some embodiments, the first surface comprises a dielectric surface. In some embodiments, the first surface comprises a material selected from a group consisting of a metal, amorphous carbon, metal oxide and metal nitride.

In some embodiments, the first surface comprises silicon. In some embodiments, the first surface comprises SiO₂. In some embodiments, the first surface comprises a metal oxide, elemental metal, or metallic surface. In some embodiments, the first surface comprises material selected from a group consisting of SiO₂, SiN, SiC, SiOC, SiON, SiOCN, SiGe and combinations thereof. In some embodiments, the second surface comprises silicon. In some embodiments, the second surface comprises SiO₂. In some embodiments, the second surface comprises a metal oxide, elemental metal, or metallic surface. In some embodiments, the second surface comprises material selected from a group consisting of SiO₂, SiN, SiC, SiOC, SiON, SiOCN, SiGe and combinations thereof.

In some embodiments, the second surface may comprise a passivated surface, for example a passivated metal surface, such as a Cu surface. That is, in some embodiments, the second surface may comprise a metal surface comprising a passivation layer, for example an organic passivation layer such as a benzotriazole (BTA) layer. In some embodiments, the passivated second metal surface is treated with an alkylsilane comprising alkylsilane having an alkoxy group bonded to a silicon atom. In some embodiments, a passivated second dielectric surface comprises silylation.

In some embodiments, the first surface is a metal or a metallic surface. In some embodiments, the first surface comprises metal. In some embodiments, the first surface comprises metallic material.

In some embodiments, the first surface is a high k surface, and the second surface is a silicon-containing dielectric surface, such as a silicon oxide surface or a low k surface, e.g. SiOC surface.

In some embodiments, the first surface is an electrically conductive surface. In some embodiments, the first surface comprises a material selected from a group consisting of a metal, amorphous carbon, metal oxide and metal nitride. In some embodiments, the first surface comprises a transition metal. In some embodiments, the first surface comprises elemental metal. In some embodiments, the first surface is elemental metal.

In some embodiments, the first surface comprises elemental tungsten. In some embodiments, the first surface is elemental tungsten. In some embodiments, the first surface comprises elemental cobalt. In some embodiments, the first surface is elemental cobalt. In some embodiments, the first surface comprises titanium nitride. In some embodiments, the first surface is titanium nitride. In some embodiments, the first surface comprises tantalum nitride. In some embodiments, the first surface is tantalum nitride. In some embodiments, the first surface comprises aluminum nitride. In some embodiments, the first surface is aluminum nitride. An elemental metal surface may comprise surface oxidation.

In some embodiments, the first surface comprises a metal selected from a group consisting of Ti, V, Nb, Ta, Cr, Mo, W, Mn, Fe, Co, Ni, Cu, Zn, Ru and Al. Thus, in some embodiments, the first surface comprises titanium. In some embodiments, the first surface comprises vanadium. In some embodiments, the first surface comprises niobium. In some embodiments, the first surface comprises tantalum. In some embodiments, the first surface comprises chromium. In some embodiments, the first surface comprises molybdenum. In some embodiments, the first surface comprises tungsten. In some embodiments, the first surface comprises manganese. In some embodiments, the first surface comprises iron. In some embodiments, the first surface comprises cobalt. In some embodiments, the first surface comprises nickel. In some embodiments, the first surface comprises copper. In some embodiments, the first surface comprises zinc. In some embodiments, the first surface comprises ruthenium. In some embodiments, the first surface comprises aluminum.

In some embodiments, the first surface comprises elemental titanium. In some embodiments, the first surface comprises elemental vanadium. In some embodiments, the first surface comprises elemental niobium. In some embodiments, the first surface comprises elemental tantalum. In some embodiments, the first surface comprises elemental chromium. In some embodiments, the first surface comprises elemental molybdenum. In some embodiments, the first surface comprises elemental tungsten. In some embodiments, the first surface comprises elemental manganese. In some embodiments, the first surface comprises elemental iron. In some embodiments, the first surface comprises elemental cobalt. In some embodiments, the first surface comprises elemental nickel. In some embodiments, the first surface comprises elemental copper. In some embodiments, the first surface comprises elemental zinc. In some embodiments, the first surface comprises elemental ruthenium. In some embodiments, the first surface comprises elemental aluminum.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the first metal or metallic surface comprises a conductive metal carbide. In some embodiments, the metal or metallic surface comprises a conductive metal boride. In some embodiments, the first metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the substrate comprises a first metal or metallic surface and second dielectric surface. In some embodiments, the substrate comprises a first metal nitride surface. In some embodiments, the substrate comprises a first electrically conductive metal nitride surface. In some embodiments, the first surface may comprise H terminations. In some embodiments, the second surface may be a SiO₂-based surface. In some embodiments, the second surface may comprise Si—O bonds. In some embodiments, the second surface may comprise a SiO₂-based low-k material. In some embodiments, the second surface may comprise more than about 30%, or more than about 50% of SiO₂. In certain embodiments the second surface may comprise a silicon dioxide surface.

In some embodiments, the first surface is a metal surface and the second surface is a SiO₂ surface. In some embodiments, the first surface is a metal surface, such as an elemental metal surface, and the second surface is a SiN surface. In some embodiments, the first surface is a metal surface, and the second surface is a SiOC surface. In some embodiments, the first surface is a metal surface, and the second surface is a SiON surface. In some embodiments, the first surface is a metal surface, and the second surface is a SiOCN surface. The first metal surface may be, for example, a copper surface, a ruthenium surface, a tungsten surface, a cobalt surface or a molybdenum surface. In some embodiments the first surface comprises a metal oxide. In some embodiments, the first surface comprises aluminum oxide. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the first surface comprises a metal selected from a group consisting of zirconium, hafnium, vanadium, niobium, tantalum, molybdenum, tungsten, iron, ruthenium, cobalt, nickel, copper, zinc, aluminum, gallium, indium and tin. The metal may be elemental metal, metal oxide, metal nitride or a mixture thereof. In some embodiments, the first surface comprises a transition metal.

In some embodiments, the second surface is a metal or a metallic surface. In some embodiments, the second surface comprises metal. In some embodiments, the second surface comprises metallic material. In some embodiments, the second surface is a high k surface, and the first surface is a silicon-containing dielectric surface, such as a silicon oxide surface or a low k surface, e.g. SiOC surface.

In some embodiments, the second surface is an electrically conductive surface. In some embodiments, the second surface comprises a material selected from a group consisting of a metal, amorphous carbon, metal oxide and metal nitride. In some embodiments, the second surface comprises a transition metal. In some embodiments, the second surface comprises elemental metal. In some embodiments, the second surface is elemental metal.

In some embodiments, the second surface comprises elemental tungsten. In some embodiments, the second surface is elemental tungsten. In some embodiments, the second surface comprises elemental cobalt. In some embodiments, the second surface is elemental cobalt. In some embodiments, the second surface comprises titanium nitride. In some embodiments, the second surface is titanium nitride. In some embodiments, the second surface comprises tantalum nitride. In some embodiments, the second surface is tantalum nitride. In some embodiments, the second surface comprises aluminum nitride. In some embodiments, the second surface is aluminum nitride. An elemental metal surface may comprise surface oxidation.

In some embodiments, the second surface comprises a metal selected from a group consisting of Ti, V, Nb, Ta, Cr, Mo, W, Mn, Fe, Co, Ni, Cu, Zn, Ru and Al. Thus, in some embodiments, the second surface comprises titanium. In some embodiments, the second surface comprises vanadium. In some embodiments, the second surface comprises niobium. In some embodiments, the second surface comprises tantalum. In some embodiments, the second surface comprises chromium. In some embodiments, the second surface comprises molybdenum. In some embodiments, the second surface comprises tungsten. In some embodiments, the second surface comprises manganese. In some embodiments, the second surface comprises iron. In some embodiments, the second surface comprises cobalt. In some embodiments, the second surface comprises nickel. In some embodiments, the second surface comprises copper. In some embodiments, the second surface comprises zinc. In some embodiments, the second surface comprises ruthenium. In some embodiments, the second surface comprises aluminum.

In some embodiments, the second surface comprises elemental titanium. In some embodiments, the second surface comprises elemental vanadium. In some embodiments, the second surface comprises elemental niobium. In some embodiments, the second surface comprises elemental tantalum. In some embodiments, the second surface comprises elemental chromium. In some embodiments, the second surface comprises elemental molybdenum. In some embodiments, the second surface comprises elemental tungsten. In some embodiments, the second surface comprises elemental manganese. In some embodiments, the second surface comprises elemental iron. In some embodiments, the second surface comprises elemental cobalt. In some embodiments, the second surface comprises elemental nickel. In some embodiments, the second surface comprises elemental copper. In some embodiments, the second surface comprises elemental zinc. In some embodiments, the second surface comprises elemental ruthenium. In some embodiments, the second surface comprises elemental aluminum.

In some embodiments, a metallic surface comprises titanium nitride. In some embodiments, the metal or metallic surface comprises one or more noble metals, such as Ru. In some embodiments, the metal or metallic surface comprises a conductive metal oxide. In some embodiments, the metal or metallic surface comprises a conductive metal nitride. In some embodiments, the second metal or metallic surface comprises a conductive metal carbide. In some embodiments, the metal or metallic surface comprises a conductive metal boride. In some embodiments, the second metal or metallic surface comprises a combination conductive materials. For example, the metal or metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

In some embodiments, the substrate comprises a second metal or metallic surface and first dielectric surface. In some embodiments, the substrate comprises a second metal nitride surface. In some embodiments, the substrate comprises a second electrically conductive metal nitride surface. In some embodiments, the second surface may comprise H terminations. In some embodiments, the second surface may be a SiO₂-based surface. In some embodiments, the second surface may comprise Si—O bonds. In some embodiments, the second surface may comprise a SiO₂-based low-k material. In some embodiments, the second surface may comprise more than about 30%, or more than about 50% of SiO₂. In certain embodiments the second surface may comprise a silicon dioxide surface.

In some embodiments, the second surface is a metal surface and the second surface is a SiO₂ surface. In some embodiments, the second surface is a metal surface, such as an elemental metal surface, and the second surface is a SiN surface. In some embodiments, the second surface is a metal surface, and the second surface is a SiOC surface. In some embodiments, the second surface is a metal surface, and the second surface is a SiON surface. In some embodiments, the second surface is a metal surface, and the second surface is a SiOCN surface. The second metal surface may be, for example, a copper surface, a ruthenium surface, a tungsten surface, a cobalt surface or a molybdenum surface. In some embodiments the second surface comprises a metal oxide. In some embodiments, the second surface comprises aluminum oxide. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the second surface comprises a metal selected from a group consisting of zirconium, hafnium, vanadium, niobium, tantalum, molybdenum, tungsten, iron, ruthenium, cobalt, nickel, copper, zinc, aluminum, gallium, indium and tin. The metal may be elemental metal, metal oxide, metal nitride or a mixture thereof. In some embodiments, the first surface comprises a transition metal.

In some embodiments, the first surface is a silicon-comprising surface, such as a dielectric surface. In some embodiments, the first surface comprises material selected from a group consisting of SiO₂, SiN, SiC, SiOC, SiON, SiOCN, SiGe and combinations thereof. In some embodiments, the first surface is a dielectric surface. In some embodiments, the first surface is a low-k surface. By a low k surface is herein meant a surface having at most a similar k value as silicon oxide. In some embodiments, the first surface comprises an oxide. In some embodiments, the first surface comprises a nitride. In some embodiments, the first surface comprises silicon. In some embodiments, the first surface comprises silicon-based dielectric material. Examples of silicon-comprising dielectric materials include silicon oxide-based materials, including grown or deposited silicon dioxide, doped and/or porous oxides and native oxide on silicon. In some embodiments, the first surface comprises silicon oxide. In some embodiments, the first surface is a silicon oxide surface, such as a native oxide surface, a thermal oxide surface or a chemical oxide surface. In some embodiments, the first surface comprises carbon. In some embodiments, the first surface comprises SiN. In some embodiments, the first surface comprises SiOC. In some embodiments, the first surface is an etch-stop layer. An etch-stop layer may comprise, for example a nitride.

In some embodiments, the second surface is a silicon-comprising surface, such as a dielectric surface. In some embodiments, the second surface comprises material selected from a group consisting of SiO₂, SiN, SiC, SiOC, SION, SiOCN, SiGe and combinations thereof. In some embodiments, the second surface is a dielectric surface. In some embodiments, the second surface is a low-k surface. In some embodiments, the second surface comprises an oxide. In some embodiments, the second surface comprises a nitride. In some embodiments, the second surface comprises silicon. In some embodiments, the second surface comprises silicon-based dielectric material. Examples of silicon-comprising dielectric materials include silicon oxide-based materials, including grown or deposited silicon dioxide, doped and/or porous oxides and native oxide on silicon. In some embodiments, the second surface comprises silicon oxide. In some embodiments, the second surface is a silicon oxide surface, such as a native oxide surface, a thermal oxide surface or a chemical oxide surface. In some embodiments, the second surface comprises carbon. In some embodiments, the second surface comprises SiN. In some embodiments, the second surface comprises SiOC. In some embodiments, the second surface is an etch-stop layer. An etch-stop layer may comprise, for example a nitride.

The substrate may be heated at stage 102 prior to providing a vapor-phase inhibitor reactant into the reaction chamber.

At stage 104, a first vapor-phase organic reactant is provided into the reaction chamber. A first organic reactant according to the current disclosure comprises a cyclic compound comprising at least two primary amine groups. Providing a first organic reactant into the reaction chamber leads to contacting the substrate with the first organic reactant. Thus, in an aspect, the process comprises contacting the substrate with a first vapor-phase organic reactant.

For providing the first organic reactant into the reaction chamber in vapor phase, the first organic reactant is vaporized. In some embodiments, the temperature at which the vapor pressure of the first organic reactant is 1 Torr is lower than 40° C., or lower than 20° C. In some embodiments, the vapor pressure of a first organic reactant according to the current disclosure is 1 Torr at a temperature of about 40° C. or less. In some embodiments, the vapor pressure of a first organic reactant according to the current disclosure is 1 Torr at a temperature of about 30° C. or less. In some embodiments, the vapor pressure of a first organic reactant according to the current disclosure is 1 Torr at a temperature of about 20° C. or less.

A vapor pressure of approximately 1 Torr may be considered sufficient for vaporizing a reactant. A low temperature at which such vapor pressure is achieved may be advantageous for performing vapor deposition processes.

In some embodiments, the first organic reactant is vaporized at a first temperature to form the first vapor-phase reactant. In some embodiments, the first organic reactant vapor is transported to the substrate through a gas line at a second temperature. In some embodiments, the second temperature is higher than the first temperature. In some embodiments, the substrate may be contacted with the first vapor-phase reactant at a third temperature. Thus, the reaction chamber temperature and/or the susceptor temperature may be different than the vaporization temperature and the gas line. In some embodiments, the third temperature is higher than the first temperature. In some embodiments, the third temperature is higher than the second temperature. In some embodiments, the third temperature is higher than the first temperature and the second temperature. In some embodiments, the third temperature is a susceptor temperature. In some embodiments, the substrate is held at a temperature higher than about 100° C. during deposition of the organic polymer material. In some embodiments, the substrate is held at a temperature of from about 100° C. to about 200° C. during the deposition of organic polymer material. In some embodiments, the substrate is held at a temperature of from about 150° C. to about 190° C., such as at a temperature of about 160° C. or about 170° C. during the deposition of organic polymer material.

In some embodiments, the substrate is held at a temperature of from about 150° C. to about 200° C. during the deposition of organic polymer material. In some embodiments, the substrate is held at a temperature of from about 150° C. to about 190° C. during the deposition of organic polymer material. In some embodiments, the substrate is held at a temperature of from about 100° C. to about 160° C. during the deposition of organic polymer material. In some embodiments, the substrate is held at a temperature of from about 150° C. to about 170° C. during the deposition of organic polymer material. In some embodiments, the substrate is held at a temperature of from about 120° C. to about 200° C., such as at about 140° C. or about 160° C. or about 180° C. or about 190° C. during the deposition of organic polymer material. In some embodiments, the deposition of organic polymer material is performed at a temperature of below 200° C.

Without limiting the current disclosure to any specific theory, the deposition temperature, such as the reaction chamber temperature or the susceptor temperature, may influence the growth rate of the organic polymer material. In some embodiments, the growth rate of the organic polymer material according to the current disclosure at a temperature of about 150° C. to about 180° C. varies from about 0.2 Å/cycle to about 2 Å/cycle, such as about 0.5 Å/cycle, 0.8 Å/cycle, about 1 Å/cycle or about 1.5 Å/cycle. This is lower than for some other types of first organic reactants. Lower growth rate may, however, correlate with some advantageous properties of the resulting organic polymer material, such as polyimide-containing material. For example, the proportion of polyimide to polyamic acid in the material may be larger. A larger proportion of polyimide compared to polyamic acid may make the organic polymer material less sensitive to etching processes, such as plasma etching process (for example hydrogen plasma etching). This again may make the regulation of etch-back or trimming processes easier, leading to a broader selectivity window in area-selective deposition processes. It may also be possible to include plasma step in downstream deposition step or steps, since the organic layer deposited on the first surface may be able to withstand plasma exposure without loss of its desired functionality. Another advantage of lower growth rate of organic polymer material according to the current disclosure may be reduced lateral growth of the organic polymer material. Thus, less of the selectively deposited organic polymer material may grow sideways on unwanted surfaces.

When the first organic reactant is provided into the reaction chamber at stage 104, it will become in contact with the substrate. Without limiting the current disclosure to any specific theory, first organic reactant may be selectively chemisorbed on the first surface of the substrate relative to the seconds surface of the substrate. In some embodiments, the first vapor-phase reactant is provided into the reaction chamber at stage 104 for a first exposure period (first organic reactant pulse time). In some embodiments, the first organic reactant pulse time is from about 0.01 seconds to about 60 seconds, about 0.05 seconds to about 30 seconds, about 0.1 seconds to about 10 seconds or about 0.2 seconds to about 5 seconds. The optimum exposure period can be determined experimentally based on the particular circumstances, such as substrate properties and the composition of the first surface and the second surface. In some embodiments, such as embodiments where batch reactors are used, exposure periods of greater than 60 seconds may be employed.

The first vapor-phase reactant comprises a cyclic compound comprising at least two primary amine groups. In some embodiments, the cyclic compound comprises a bicyclic ring. In some embodiments, the bicyclic compound contains fused rings. In some embodiments, the bicyclic compound contains separate rings. In some embodiments, the cyclic compound comprises a single ring with at least two NH₂-containing substituents. In some embodiments, the cyclic compound comprises a carbocycle. In some embodiments, the carbocycle is a C3 to C8 ring. In some embodiments, the carbocycle is a 3-membered ring. In some embodiments, the carbocycle is a 4-membered ring. In some embodiments, the carbocycle is a 5-membered ring. In some embodiments, the carbocycle is a 6-membered ring. In some embodiments, the carbocycle is a 7-membered ring. In some embodiments, the carbocycle is an 8-membered ring. In some embodiments, the carbocycle is aliphatic (i.e. an alicyclic compound). An alicyclic carbocycle may be saturated or unsaturated.

In some embodiments, the cyclic compound comprises an aromatic ring. In some embodiments, the cyclic compound does not comprise an aromatic ring. In some embodiments, the cyclic compound does not comprise p-phenylenediamine. In some embodiments, the cyclic compound comprises an alicyclic ring. In some embodiments, the cyclic compound comprises a six-membered carbocycle comprising two primary amine groups, bonded directly or indirectly to positions 1 and 4 of the carbon ring, respectively. In some embodiments, the cyclic compound comprises a six-membered carbocycle comprising two primary amine groups, bonded directly to positions 1 and 4 of the carbon ring, respectively. In some embodiments, the cyclic compound comprises a six-membered carbocycle comprising three primary amine groups, bonded directly or indirectly to positions 1, 3 and 5 of the carbon ring, respectively. In some embodiments, the cyclic compound comprises a six-membered carbocycle comprising three primary amine groups, bonded directly to positions 1, 3 and 5 of the carbon ring, respectively. In some embodiments, the cyclic compound comprises at least one of cyclopentanedialkanamine, cyclohexanedialkanamine, cyclopentadienedialkanamine, benzenedialkanamine, cyclopentanetrialkanamine, cyclohexanetrialkanamine, cyclopentadienetrialkanamine and benzenetrialkanamine. Each alkyl of said alkanamines may be independently selected from methyl, ethyl, propyl (including n-propyl and isopropyl) and butyl (including n-butyl, sec-butyl, isobutyl and tert-butyl).

In some embodiments, the non-aromatic cyclic diamine compound is a trans isomer of the compound. In some embodiments, the non-aromatic cyclic diamine compound is a cis isomer of the compound. In some embodiments, the non-aromatic cyclic diamine compound is a mixture of cis and trans isomers of the compound. Without limiting the current disclosure to any specific theory, trans isomers of the cyclic compounds may have more desired reactivity and usability in the processes according to the current disclosure.

In some embodiments, the cyclic compound is selected from a group consisting of 1,3-cyclopentanediamine, 3,5-cyclopentadiene-1,3-diamine, 2,4-cyclopentadiene-1,3-diamine, 1,3-cyclopentanedimethanamine, 3,5-cyclopentadiene-1,3-dimethanamine, 2,4-cyclopentadiene-1,3-dimethanamine, 1,4-diaminocyclohexane, 1,3-cyclohexanediamine, 1,2-cyclohexanediamine, 1,4-cyclohexanedimethanamine, 1,3-cyclohexanedimethanamine, 1,2-cyclohexanedimethanamine, 1,4-cyclohexanediethanamine, 1,3-cyclohexanediethanamine, 1,2-cyclohexanediethanamine, 1,2,3-cyclopentanetriamine, 1,2,4-cyclopentanetriamine, 1,3-cyclopentadiene-1,2,4-triamine, 1,2,3-cyclohexanetriamine, 1,2,4-cyclohexanetriamine, 1,3,5-cyclohexanetriamine, 1,3,5-cyclohexanetrimethanamine, p-phenylenediamine, m-phenylenediamine, o-phenylenediamine, 1,4-benzenedimethanamine, 1,3-benzenedimethanamine, 1,2-benzenedimethanamine, 1,2,3-benzenetriamine, 1,2,4-benzenetriamine, 1,3,5-benzenetriamine, 1,2,3-benzenetrimethanamine, 1,2,4-benzenetrimethanamine and 1,3,5-benzenetrimethanamine.

In some embodiments, the first organic reactant is selected from compounds having a cyclopentane, cyclopentadiene, cyclohexane or a benzene ring and two primary amine containing substituents, wherein the amine containing substituents are independently selected from —NH₂, —CH₂NH₂ and —CH₂CH₂NH₂. Thus, the substituents may be the same, such as both substituents are —NH₂, or both substituents are —CH₂NH₂ or both substituents are —CH₂CH₂NH₂. The substituents may be different. For example, one substituent may be —NH₂, and the second one —CH₂NH₂. One substituent may be —NH₂, and the second one —CH₂CH₂NH₂. One substituent may be —CH₂CH₂NH₂, and the second one —CH₂NH₂.

In some embodiments, the first organic reactant is selected from compounds having a cyclopentane, cyclopentadiene, cyclohexane or a benzene ring and three primary amine containing substituents, wherein the amine containing substituents are independently selected from —NH₂, —CH₂NH₂ and —CH₂CH₂NH₂. Thus, the substituents may be the same, such as all three substituents are —NH₂, or all three substituents are —CH₂NH₂ or all three substituents are —CH₂CH₂NH₂. The substituents may be different. For example, one substituent may be —NH₂, and the second one —CH₂NH₂ and the third one —CH₂CH₂NH₂. One substituent may be —NH₂, and the two other substituents —CH₂NH₂. One substituent may be —CH₂NH₂, and the two other substituents —NH₂. One substituent may be —NH₂, and the two other substituents —CH₂CH₂NH₂. One substituent may be —CH₂CH₂NH₂, and the two other substituents —NH₂. One substituent may be —CH₂NH₂, and the two other substituents —CH₂CH₂NH₂. One substituent may be —CH₂CH₂NH₂, and the two other substituents —CH₂NH₂.

At stage 105, the reaction chamber is optionally purged of the first vapor-phase reactant and/or any reaction by-products. This phase of the process may be omitted in some embodiments. However, in many embodiments purging is used. In some embodiments, purging is performed by providing an inert gas, such as a carrier gas, into the reaction chamber for a period of time (purge time). In some embodiments, N₂ gas is used in purging. In some embodiments, purge time is from about 0.5 seconds to about 10 seconds, such as from about 1 second to about 5 seconds, for example 1 second, 2 seconds, 4 seconds, 6 seconds or 8 seconds.

At stage 106, a second vapor-phase reactant is provided into the reaction chamber. In some embodiments, the second reactant is also an organic reactant capable of reacting with adsorbed species of the first organic reactant under the deposition conditions. For example, the second reactant can be an anhydride, such as furan-2,5-dione (maleic acid anhydride), or more particularly a dianhydride, e.g., pyromellitic dianhydride (PMDA), or any other monomer with two reactive groups which will react with the first organic reactant. In some embodiments, the second vapor-phase reactant comprises a dianhydride. In some embodiments, the second vapor-phase reactant comprises pyromellitic dianhydride (PMDA).

In some embodiments, a second vapor-phase reactant is provided into the reaction chamber at stage 106 for a second exposure period (second reactant pulse time). In some embodiments, the second reactant may be vaporized at a fourth temperature to form the second vapor-phase reactant. In some embodiments, the second reactant vapor is transported to the substrate through a gas line at a fifth temperature. In some embodiments, the fifth temperature is higher than the first temperature. In some embodiments, the second vapor-phase reactant is provided into the reaction chamber at a sixth temperature that is higher than the fourth temperature. In some embodiments, the sixth temperature is substantially the same as the third temperature.

In some embodiments, the first organic reactant is provided into the reaction chamber prior to the second reactant being provided into the reaction chamber. However, in some embodiments, the second reactant, such as a dianhydride, is provided into the reaction chamber prior to providing the first organic reactant into the reaction chamber. Thus, in some embodiments, the substrate is contacted with an anhydride, such as furan-2,5-dione (maleic acid anhydride), or more particularly a dianhydride, e.g., pyromellitic dianhydride (PMDA) prior to being contacted with another reactant.

In the method according to the current disclosure, the first and second vapor-phase reactants form the organic polymer material selectively on the first surface relative to the second surface. In some embodiments, the organic polymer material comprises polyimide. In some embodiments, the organic polymer material comprises polyamic acid. In some embodiments, the organic polymer material comprises polyimide and polyamic acid. Without limiting the current disclosure to any specific theory, the selectivity may be at least partially due to the preferential chemisorption of the first organic reactant on the first surface. In some embodiments, the organic polymer material is deposited on the first surface relative to the second surface with a selectivity of about 50% or higher. In some embodiments, the organic polymer material is deposited substantially only on the first surface and not on the second surface.

In an aspect, the organic polymer material according to the current disclosure forms a layer of organic polymer material (i.e. an organic polymer layer). The deposition methods disclosed herein may result in an advantageous organic polymer material composition. For example, in some embodiments, the ratio of vertical growth to lateral growth of the organic polymer material over the first surface is at least 2.5 or at least 3, or at least 5, or at least 7. In some embodiments, such as when using a non-aromatic first organic reactant, the ratio of vertical growth to lateral growth of the organic polymer material may be at least 8. The higher the ratio of vertical growth to lateral growth of the organic polymer is, the better defined the selective deposition may be, causing correspondingly smaller line edge roughness. Especially first organic reactants having an alicyclic six-membered ring were discovered to have a high ratio of vertical growth to lateral growth.

In some embodiments, the coefficient of thermal expansion of the organic polymer material may be lower when a cyclic first organic reactant is used compared to non-cyclic reactants. Due to the cyclic form of the first organic reactant, the thermal expansion of the resulting organic polymer material may be reduced compared to organic polymer materials in which non-cyclic amine-containing organic reactants are used. It may also be that the initial temperature-induced shrinkage of the deposited organic polymer is smaller for organic polymers deposited using cyclic first organic reactant. For example, for organic polymer material deposited using an aromatic cyclic first organic reactant, the shrinkage may be less than 10% or less than 5% of the original material layer thickness. When non-aromatic first organic reactant was used, shrinkage under similar conditions was approximately 35-40%.

At stage 107, the reaction chamber is optionally purged of the second vapor-phase reactant and/or any reaction by-products. This phase of the process may be omitted in some embodiments. However, in many embodiments purging is used. In some embodiments, purging is performed by providing an inert gas, such as a carrier gas, into the reaction chamber for a period of time (purge time). In some embodiments, N₂ gas is used in purging. In some embodiments, purge time is from about 0.5 seconds to about 10 seconds, such as from about 1 second to about 5 seconds, for example 1 second, 2 seconds, 4 seconds, 6 seconds or 8 seconds.

The use of purge stages 105 and 107 is independently optional. Thus, both or either one of the stages 105 and 107 may be performed, and the parameters, such as duration and composition of the purge gas, may be independently selected. In some embodiments, each deposition cycle comprises removing excess of the first vapor-phase reactant and reaction by-products after providing the first vapor-phase reactant into the reaction chamber. In some embodiments, each deposition cycle comprises removing excess of the second vapor-phase reactant and reaction by-products after providing the second vapor-phase reactant into the reaction chamber. However, it is possible that a deposition process comprises one or more cycles in which the purge stage is omitted. Thus, for simplicity, in the context of purging, each deposition cycle may mean “substantially each deposition cycle”.

The selective deposition process according to the current disclosure is a cyclic process. The thickness of the deposited organic polymer material layer is determined, in addition to the conditions during providing the first organic reactant and the second reactant into the reaction chamber, by the number of deposition cycles 108 performed. In some embodiments, a deposition cycle comprises stages 104 and 106. In some embodiments, a deposition cycle comprises stages 104 and 106, as well as one or both of 105 and 107. In some embodiments, a deposition cycle comprises stages 104, 105, 106 and 107. In some embodiments, the first organic reactant and the second reactant are provided into the reaction chamber alternately and sequentially.

In some embodiments, a deposition cycle may be repeated until an organic layer of a desired thickness is selectively deposited. The selective deposition cycle can include additional acts, need not be in the same sequence nor identically performed in each repetition, and can be readily extended to more complex vapor deposition techniques. For example, a selective deposition cycle can include additional reactant supply processes, such as the supply and removal (relative to the substrate) of additional reactants in each cycle or in selected cycles. Though not shown, the process may additionally comprise treating the deposited film to form a polymer (for example, UV treatment, annealing, etc.).

The method 100 may further comprise subjecting the substrate to an etch process 109 subsequent to multiple consecutive deposition cycles. The etch stage 109 may be performed once at the end of the deposition process, or it can be performed intermittently after a predetermined number of deposition cycles, as depicted by loop 110. After an etching process, the selective deposition of organic polymer material may be continued.

In some embodiments, the etching 109 removes substantially all of any deposited organic polymer material from the second surface of the substrate and does not remove substantially all of the deposited organic polymer material from the first surface of the substrate. In some embodiments, the etch process may comprise exposing the substrate to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may also comprise noble gas species, for example Ar or He species. Thus, in some embodiments, the etch process comprises exposing the substrate to hydrogen atoms, hydrogen radicals, hydrogen plasma, or combinations thereof. In some embodiments, the etch process comprises exposing the substrate to oxygen atoms, oxygen radicals, oxygen plasma, or combinations thereof. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., for example between about 100° C. and about 400° C. or between about 100° C. and about 300° C. In some embodiments, the etchant may be supplied in one continuous pulse or may be supplied in multiple shorter pulses. A purge stage may be performed between etching pulses.

As a non-limiting example, reactive species generated from hydrogen- and argon-comprising plasma can be used to treat the deposited organic polymer material. The plasma treatment may etch the deposited organic polymer material, but, instead or in addition, it may modify the surface of the organic polymer material to improve its properties as a passivation layer. The organic polymer may be exposed to plasma from about 1 seconds to about 1 minute, such as from about 1 second to about 30 seconds, or from about 5 seconds to about 30 seconds, or for about 1 second to about 15 seconds, or from about 3 seconds to about 20 seconds, for example for about 5 seconds, for about 10 seconds, for about 20 seconds or for about 30 seconds. A plasma power of at least about 20 W or at least about 50 W, such as from about 20 W to about 100 W, such as 30 W, 50 W or 70 W, may be used. The suitable plasma power and duration of the plasma exposure may be determined experimentally.

In some embodiments, the substrate may be subjected to an etch process to remove at least a portion of the deposited organic film. In some embodiments, an etch process subsequent to selective deposition of the organic film may remove deposited organic polymer material from both the first surface and the second surface of the substrate. In some embodiments, the etch process may be isotropic.

In some embodiments, the etch process may remove the same amount, or thickness, of organic polymer material from the first and second surfaces. That is, in some embodiments, the etch rate of the organic polymer material deposited on the first surface may be substantially similar to the etch rate of the organic polymer material deposited on the second surface. Due to the selective nature of the deposition processes described herein, the amount of organic polymer material deposited on the second surface of the substrate may be substantially less than the amount of material deposited on the first surface of the substrate. Therefore, an etch process may completely remove deposited organic polymer material from the second surface of the substrate while deposited organic polymer material may remain on the first surface of the substrate.

The diamine compounds according to the current disclosure may be used to deposit organic polymer material that is more resistant to an etch process, for example to an etch process performed by hydrogen plasma as an etchant. This may be advantageous, as it may allow for easier tuning of an etching process, which again may enable a broader selectivity window for the process.

In some embodiments, the organic polymer material is an organic passivation material. In some embodiments, the organic passivation material forms a passivation layer on the first surface. By a passivation material is herein meant a material that reduces or prevents the accumulation of another deposited material on the surface covered by the passivation material.

Depending on the selection on the first organic reactant, the deposition of the organic polymer material on a given surface can be adjusted. For example, in tests performed using 1,4-diaminocyclohexane, it was discovered that the organic polymer material grew preferentially on dielectric material comprising silicon relative to tested metal or metallic surfaces Co, W, TiN and TaN. However, using 1,4-diaminobenzene as the first organic reactant, organic polymer material grew faster on silicon-based surfaces similarly to organic polymers grown using linear or branched di- or triamine compounds.

A second option to regulate the selectivity of organic polymer material deposition is to use an inhibitor before depositing the organic polymer material. For example, silylating agents, such as N-(trimethylsilyl)dimethylamine as inhibitors, the deposition of organic polymer material on silicon-comprising surfaces may be substantially omitted, or significantly reduced. This may allow using the organic polymer material as passivation on metal or metallic surfaces, which further enables selective deposition of materials of interest on the silicon-comprising surfaces-optionally after removal of the inhibitor from the silicon-comprising surfaces. Conversely, using, for example, bis(tert-pentoxy)methylsilanol, bis(tert-butoxy)methylsilanol or bis(tert-pentoxy)ethylsilanol, or other alkoxy group-containing silanes or silanols as an inhibitors, the deposition of organic polymer material on metal or metallic surfaces may be prevented, which allows the opposite deposition scheme (i.e. deposition on metals and metallic materials) for the target material in question, such as silicon oxide, aluminum oxide, yttrium oxide, or a combination thereof. In some embodiments, the target material is a dielectric oxide material.

The selective deposition according to the current disclosure was tested using 1,4-diaminocyclohexane and pyromellitic dianhydride as the first and second organic reactants, respectively, for depositing polyimide-comprising organic polymer material. The growth of the organic polymer material was observed already at 20 deposition cycles on native silicon oxide, whereas for metals and metallic materials (Co, TaN, TiN and W), growth was observed much later, notably for Co and TiN at around 50 cycles, and for W and TaN not before 100 cycles into the deposition process. Measured in thickness, difference between the native silicon oxide surface and the W surface was 10 nm.

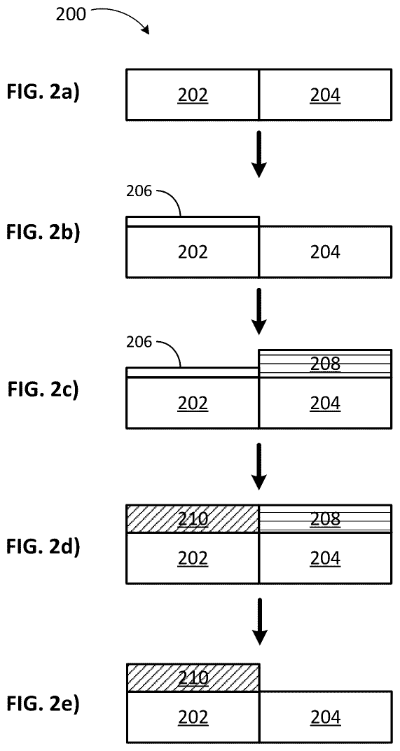

FIGS. 2a)-2c) show a schematic presentation of exemplary embodiments of a method according to the current disclosure. FIGS. 2 a)-e) illustrate an embodiment of a method according to the current disclosure schematically. In the FIG. 2a), a substrate 200 comprising a first surface 202 and a second surface 204 is depicted. In FIG. 2b) an inhibitor material 206, such as a alkylamines, alkoxy group-containing silanes or silanols, is deposited on the first surface 202 relative to the second surface 204. In FIG. 2c) the second surface 204 is selectively passivated by an organic passivation layer 208 relative to the first surface 202 comprising the inhibitor layer 206. In FIG. 2d) selective deposition of a dielectric layer 210 on the first surface 202 relative to the passivated second surface 204 is performed.

More specifically, FIG. 2a) illustrates a substrate 200 having two surfaces 202, 204 having different material properties. The first surface 202 may comprise, consist essentially of, or consist of a metal, such as Cu, W or Mo, or a metallic material, such as TiN as disclosed herein. The second surface 204 may comprise, consist essentially of, or consist of silicon oxide-based material or another dielectric material, such as silicon-based material described in this disclosure. However, as disclosed above, the material compositions of the first surface 202 and the second surface 204 may be opposite. Depending on the selection of the inhibitor and the first organic reactant, it may be deposited either on a metal or metallic surface on the one hand, or on a silicon-containing surface or a dielectric surface on the other.

In some embodiments, the first surface is a dielectric surface, and the second surface is a metal surface. In some embodiments, the first surface is a silicon-comprising dielectric surface, and the second surface is a metal surface. In some embodiments, the first surface is a high-k surface, and the second surface is a metal surface. In some embodiments, the first surface is a metal oxide surface, and the second surface is a metal surface. In some embodiments, the first surface comprises a material selected from a group consisting of HfO₂, ZrO₂, Al₂O₃, Y₂O₃, SiO₂ and combinations thereof.

FIG. 2b) shows the substrate 200 of FIG. 2a) after depositing an inhibition layer the first surface 202. Although depicted in FIGS. 2a-2e) as a layer, the inhibitor material of the first surface 202 may be very thin. FIG. 2c) shows the substrate 200 of FIG. 2b) after selective deposition of an organic polymer material, such as a passivation layer 208 on the second surface 204, for example by forming a polyimide-comprising layer.

FIG. 2d) shows the substrate 200 of FIG. 2c) following selective deposition of a material of interest 210 on the first surface. The material of interest may be dielectric material, such as a metal oxide layer or a silicon oxide layer on the first surface 202 relative to the passivated second surface 204. Any material of interest 210 deposited on the second surface 204, such as on the passivation layer 208, can be removed by a treatment, such as an etch-back process. However, this may be challenging for some materials, due to their high etch resistivity. Therefore, in many embodiments, etch back is not performed, but the selectivity of the process is high enough without it. In other embodiments, material of interest on the second surface 204 may be removed during subsequent removal of the passivation layer 208. In some embodiments, etching is used as a post-deposition process to clean up the final surfaces, and/or to remove passivation.

FIG. 2e) shows the substrate of FIG. 2d) after a post-deposition treatment to remove the passivation layer 208 from the second surface 204, such as by an etch process. In some embodiments, the etch process may comprise exposing the substrate 200 to a plasma. In some embodiments, the plasma may comprise oxygen atoms, oxygen radicals, oxygen plasma, or combinations thereof. In some embodiments, the plasma may comprise hydrogen atoms, hydrogen radicals, hydrogen plasma, or combinations thereof. In some embodiments, the plasma may comprise noble gas species, for example Ar or He species. In some embodiments, the plasma may consist essentially of noble gas species. In some embodiments, the plasma may comprise other species, for example nitrogen atoms, nitrogen radicals, nitrogen plasma, or combinations thereof. In some embodiments, the etch process may comprise exposing the substrate to an etchant comprising oxygen, for example O₃. In some embodiments, the substrate may be exposed to an etchant at a temperature of between about 30° C. and about 500° C., or between about 100° C. and about 400° C., or between about 100° C. and about 300° C. In some embodiments, the etchant may be supplied in one continuous pulse or may be supplied in multiple pulses. The removal of the passivation layer 208 can be used to lift-off any remaining dielectric material from over the second surface, either in a complete removal of the passivation layer 208 or in a partial removal of the passivation layer 208 in a cyclical selective deposition and removal.

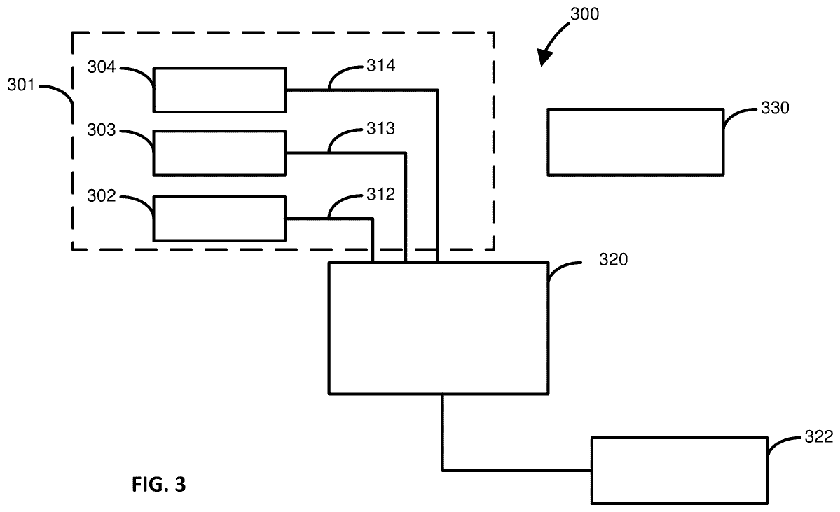

FIG. 3 is a schematic drawing of an embodiment of a semiconductor processing assembly 500 according to the current disclosure.

A semiconductor processing assembly 300 for selectively depositing an organic polymer material on a first surface of a substrate is disclosed. The semiconductor processing assembly 300 comprises one or more reaction chambers 320 constructed and arranged to hold the substrate, a precursor injector system 301 constructed and arranged to provide a first organic reactant and a second organic reactant into the reaction chamber 320 in a vapor phase. The semiconductor processing assembly 300 further comprises first organic reactant source vessel 302 constructed and arranged to contain the first organic reactant and a second organic reactant source vessel 303 constructed and arranged to contain the second organic reactant. The semiconductor processing assembly 300 is constructed and arranged to provide the first organic reactant and the second organic reactant into the reaction chamber 320 for selectively forming organic polymer material on the first surface of the substrate.

The semiconductor processing assembly 300 may comprise one or more optional further source vessels 304 constructed and arranged to contain additional reactants used in the processing of the substrate. Only one further source vessel 304 is depicted in FIG. 3 for simplicity. The precursor injector system 301 may be constructed and arranged to provide the one more precursors or additional reactants from a further source vessel 304 into the reaction chamber 320 in a vapor phase. The precursors or reactants may be precursors for depositing material of interest on a second surface of the substrate, or inhibitor reactant(s) for depositing an inhibition layer on the second surface of the substrate to prevent the organic polymer material from being deposited thereon. The precursors for a material of interest may be, for example, metal precursors, semimetal precursors, oxygen precursors, nitrogen precursors or other precursors for depositing dielectric material or other materials on the second surface of the substrate. In some embodiments, a further source vessel 304 may be constructed and arranged to hold an etchant.

The processing assembly 300 can be used to perform a method as described herein. In the illustrated example, processing assembly 300 includes one or more reaction chambers 320, a precursor injector system 301, source vessels 302, 303, 304, optional and further source vessels, an exhaust source 322, and a controller 330. The processing assembly 300 may comprise one or more additional gas sources (not shown), such as an inert gas source, a carrier gas source and/or a purge gas source. Reaction chamber 320 can include any suitable reaction chamber, such as an ALD or CVD reaction chamber as described herein.

The first organic reactant source vessel 302 can include a vessel and a first organic reactant as described herein-alone or mixed with one or more carrier (e.g., inert) gases. The second organic reactant source vessel 303 can include a vessel and a second organic reactant as described herein-alone or mixed with one or more carrier (e.g., inert) gases. Thus, although illustrated with three source vessels 302-304, a processing assembly 300 can include any suitable number of source vessels. Source vessels 302-304 can be coupled to reaction chamber 320 via lines 312-314, which can each include flow controllers, valves, heaters, and the like. In some embodiments, each of the source vessels 302-304 may be independently heated or kept at ambient temperature. In some embodiments, a source vessel is heated so that a precursor or a reactant reaches a suitable temperature for vaporization

Exhaust source 322 can include one or more vacuum pumps.

Controller 330 includes electronic circuitry and software to selectively operate valves, manifolds, heaters, pumps and other components included in the processing assembly 300. Such circuitry and components operate to introduce precursors, reactants and other gases from the respective sources. Controller 330 can control timing of gas pulse sequences, temperature of the substrate and/or reaction chamber 320, pressure within the reaction chamber 320, and various other operations to provide proper operation of the processing assembly 300. Controller 330 can include control software to electrically or pneumatically control valves to control flow of precursors, reactants and other gases into and out of the reaction chamber 320. Controller 330 can include modules such as a software or hardware component, which performs certain tasks.

Other configurations of processing assembly 300 are possible, including different numbers and kinds of source vessels. For example, a reaction chamber 320 may comprise more than one, such as two or four, deposition stations. Such a multi-station configuration may have advantages if, for example, inhibition, passivation, deposition and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 320. Further, as a schematic representation of a processing assembly 300, many components have been omitted for simplicity of illustration, and such components may include, for example, various valves, manifolds, purifiers, heaters, containers, vents, and/or bypasses.

During operation of processing assembly 300, substrates, such as semiconductor wafers (not illustrated), are transferred from, e.g., a substrate handling system to reaction chamber 320. Once substrate(s) are transferred to reaction chamber 320 (i.e. they are provided in the reaction chamber 320), one or more gases from gas sources, such as precursors, reactants, carrier gases, and/or purge gases, are introduced into reaction chamber 320.

The example embodiments of the disclosure described above do not limit the scope of the disclosure, since these embodiments are merely examples of the embodiments of the methods, structures, devices and processing assemblies, which are defined by the appended claims and their legal equivalents. Any equivalent embodiments are intended to be within the scope of this disclosure. Various modifications of the disclosure, in addition to those shown and described herein, such as alternative useful combinations of the elements described, may become apparent to those skilled in the art from the description. Such modifications and embodiments are also intended to fall within the scope of the appended claims.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of selectively depositing organic polymer material on a first surface of a substrate relative to a second surface of the substrate by a cyclic deposition process, the method comprising
providing a substrate in a reaction chamber;
providing a first vapor-phase organic reactant into the reaction chamber;
providing a second vapor-phase organic reactant into the reaction chamber;
wherein the first and second vapor-phase organic reactants form the organic polymer material selectively on the first surface; and wherein the first vapor-phase organic reactant comprises a cyclic compound comprising at least two primary amine groups.

2. The method of claim 1, wherein the second vapor-phase organic reactant comprises a dianhydride.

3. The method of claim 1, wherein the cyclic compound comprises a carbocycle.

4. The method of claim 3, wherein the cyclic compound comprises an aromatic ring.

5. The method of claim 3, wherein the cyclic compound comprises an alicyclic ring.

6. The method of claim 3, wherein the cyclic compound comprises a six-membered carbocycle comprising two primary amine groups, bonded directly or indirectly to positions 1 and 4 of a carbon ring, respectively.

7. The method of claim 3, wherein the cyclic compound comprises a six-membered carbocycle comprising three primary amine groups, bonded directly or indirectly to positions 1, 3 and 5 of a carbon ring, respectively.

8. The method of claim 3, wherein the cyclic compound comprises at least one of cyclopentanedialkanamine, cyclohexanedialkanamine, cyclopentadienedialkanamine, benzenedialkanamine, cyclopentanetrialkanamine, cyclohexanetrialkanamine, cyclopentadienetrialkanamine and benzenetrialkanamine.

9. The method of claim 3, wherein the cyclic compound is selected from a group consisting of 1,3-cyclopentanediamine, 3,5-cyclopentadiene-1,3-diamine, 2,4-cyclopentadiene-1,3-diamine, 1,3-cyclopentanedimethanamine, 3,5-cyclopentadiene-1,3-dimethanamine, 2,4-cyclopentadiene-1,3-dimethanamine, 1,4 cyclohexanediamine, 1,3-cyclohexanediamine, 1,2-cyclohexanediamine, 1,4-cyclohexanedimethanamine, 1,3-cyclohexanedimethanamine, 1,2 cyclohexanedimethanamine, 1,4-cyclohexanediethanamine, 1,3-cyclohexanediethanamine, 1,2-cyclohexanediethanamine, 1,2,3-cyclopentanetriamine, 1,2,4-cyclopentanetriamine, 1,3-cyclopentadiene-1,2,4-triamine, 1,2,3-cyclohexanetriamine, 1,2,4-cyclohexanetriamine, 1,3,5-cyclohexanetriamine, 1,3,5-cyclohexanetrimethanamine, p-phenylenediamine, m-phenylenediamine, 0-phenylenediamine, 1,4-benzenedimethanamine, 1,3-benzenedimethanamine, 1,2 benzenedimethanamine, 1,2,3-benzenetriamine, 1,2,4-benzenetriamine, 1,3,5-benzenetriamine, 1,2,3-benzenetrimethanamine, 1,2,4-benzenetrimethanamine and 1,3,5-benzenetrimethanamine.

10. The method of claim 1, wherein the organic polymer material comprises polyimide.

11. The method of claim 1, wherein the organic polymer material is deposited on the first surface relative to the second surface with a selectivity of about 50% or higher.

12. The method of claim 1, wherein a ratio of vertical growth to lateral growth of the organic polymer material over the first surface is at least 2.5.

13. The method of claim 1, wherein the coefficient of thermal expansion of the organic polymer material is below 20 ppm K-1.

14. The method of claim 1, further comprising treating the deposited organic polymer material with reactive species comprising hydrogen radicals.

15. The method of claim 1, wherein the first surface comprises a dielectric surface.

16. The method of claim 15, wherein the first surface comprises SiO₂.

17. The method of claim 1, wherein the first surface comprises a metal oxide, elemental metal, or metallic surface.

18. The method of claim 17, wherein the first surface comprises a metal selected from a group consisting of zirconium, hafnium, vanadium, niobium, tantalum, molybdenum, tungsten, iron, ruthenium, cobalt, nickel, copper, zinc, aluminum, gallium, indium and tin.

19. A method of selectively depositing organic passivation material on a first surface of a substrate relative to a second surface of the substrate; the method comprising
providing a substrate in a reaction chamber;
providing a first vapor-phase organic reactant into the reaction chamber;
providing a second vapor-phase organic reactant into the reaction chamber;
wherein the first and second vapor-phase organic reactants form the organic passivation material selectively on the first surface; and wherein the first vapor-phase organic reactant comprises a cyclic compound comprising at least two primary amine groups.

20. A method of selectively depositing a dielectric material on a second surface of a substrate, the method comprising selectively depositing organic passivation material on the first surface of the substrate according to claim 1 before depositing the dielectric material.

21. The method of claim 20, wherein the dielectric material is deposited by a cyclic deposition process.
